(19) United States
(12) Patent Application Publication
(10) Pub. No.: US 2013/0263772 A1
(43) Pub. Date: Oct. 10, 2013

(54) Method and apparatus for controlling melt temperature in a Czochralski grower

(71) Applicants: David L. Bender, Thousand Oaks, CA (US); Gary Janik, Palo Alto, CA (US); David E.A. Smith, San Mateo, CA (US)

(72) Inventors: David L. Bender, Thousand Oaks, CA (US); Gary Janik, Palo Alto, CA (US); David E.A. Smith, San Mateo, CA (US)

(21) Appl. No.: 12/315,681

(22) Filed: Dec. 4, 2008

Related U.S. Application Data
(60) Provisional application No. 61/005,384, filed on Dec. 4, 2007.

(51) Int. Cl. C30B 15/10

(52) U.S. Cl. 117/15; 117/202

(57) ABSTRACT

In a Czochralski process for growing single crystal silicon ingots, a system is provided for adding solid material to the liquid silicon during crystal growth for the purpose of directly controlling the latent heat of fusion with respect to a crystal melt interface. In contrast to the standard method for controlling power to the crucible heaters, the present system has been found to be much more effective for controlling melt temperature in the crucible, especially in heavily insulated systems. The system provides the advantages of reducing the electric power required to operate a Czochralski grower, while increasing the speed with which the melt temperature can be raised or lowered in a controlled manner.

### CROSS REFERENCE TO RELATED APPLICATION

This patent application claims the benefit of U.S. provisional application Ser. No. 61/005,384, filed Dec. 4, 2007.

### BACKGROUND

1. Field of the Invention

The field of the invention generally relates to growing single crystal silicon by the Czochralski (CZ) technique. In particular, the field of the invention relates to a system and method for controlling the characteristics of the liquid silicon from which a crystal is being pulled, resulting in improved mono-crystalline ingot yields.

2. Background of Related Art

In a conventional batch CZ process using solid recharge, a monocrystalline ingot is drawn from the melted silicon contained in a crucible. After an ingot has been pulled, the melted silicon in the crucible is replenished by added solid feedstock to the crucible and melting it. When the crucible melt level has been raised to the desired level, a seed is dipped in the melt and another crystal can start to be pulled.

This process takes non-productive time during which solid poly-crystalline feedstock is added to the crucible and crystals are not being produced. During this refilling time, the heater power is typically raised in order to melt the added solid material more quickly. When the addition of material is completed, heater power is reduced and further time is lost waiting for the melt thermal conditions to stabilize at the correct conditions for pulling a monocrystalline ingot.

During the pulling process, control of the melt temperature in a conventional CZ grower is achieved by increasing or decreasing the heater power. Reducing the melt temperature is accomplished by reducing the heater power, but this can take a long time, particularly in a well-insulated CZ grower, because the heat must exit the grower for the temperature to drop. Reducing the grower insulation allows the melt temperature to be reduced more quickly, but causes the grower to consume more energy and requires the heaters to be at higher temperature during parts of the growth cycle. Operating heaters at a higher temperature shortens their life and increases the production of gases, such as carbon monoxide, that can become dissolved in the molten silicon, contaminating and reducing the quality of the ingots produced.

Therefore, what is needed is a temperature control system that provides the capability of efficiently increasing or decreasing the melt temperature while saving energy and reducing the need for operating heaters at high temperatures, which shortens their useful life and produces gases that can contaminate the molten silicon in the grower.

### SUMMARY

In order to overcome the foregoing limitations and disadvantages inherent in a conventional CZ process for growing single crystal silicon ingots, an aspect of the invention provides for adding solid material to the liquid silicon during growth for the purpose of directly controlling the latent heat of fusion with respect to the crystal melt interface. This has been found much more effective for controlling melt temperature in the crucible than reducing the heater power, especially in heavily insulated systems. Such effectiveness is achieved in that as the solid material melts, it removes heat from the liquid faster than heat can be transported away from the liquid into the crucible and surrounding grower components. In all CZ processes, reducing the melt temperature too slowly can result in loss of structure in the growing crystal. Thus, a heavily insulated conventional CZ system is difficult to control. On the other hand, reducing temperature too quickly by extracting energy rapidly can lead to loss of structure in a growing ingot due to thermal shock.

However, when energy is extracted in a controlled manner accordance with an aspect of this invention, temperature control can be achieved without detriment to the growing ingot. Heat (energy) is extracted from the liquid silicon melt in a predictable manner relying on the specific heat of silicon (18.71 J/mol/K) and its latent heat of fusion (50,200 J/mol). Raising solid silicon from room temperature (300K) to its melting point (1687K) requires approximately 26 kJ [(1687K-300K)*18.71 J/mol/K)] of energy per mole of silicon to be removed. Additionally, melting solid silicon requires 50.2 kJ of energy per mole of silicon added. Therefore, nearly 76 kJ of energy is extracted from the silicon melt for every mole of silicon added, and this energy comes from the melt thereby cooling the molten silicon. FIG. 2 shows the change in temperature of a silicon melt as a function of time while solid silicon is added to the melt at a constant rate.

A further aspect of the invention is that it provides a means for increasing the temperature in the melt more efficiently by using heater power. This can be more effective than temperature control in conventional CZ growers, because the melt region can be better insulated than would be practical in a conventional grower. In a conventional CZ grower, too much insulation makes it difficult to remove heat from the melt by radiation or conduction when the process requires it. Because an aspect of the invention provides a different means for controllably reducing melt temperature, better insulation can be provided around the heaters. This reduces the heater power required and makes the melt temperature increase more rapidly as heater power is increased. This also makes it possible to achieve the same melt temperatures while operating the heaters at lower temperatures. Lower operating temperatures extend the useful heater lifetime and reduce significantly the production of gases at the heaters that can contaminate the silicon melt, and critically degrade the quality of the silicon ingots.

The foregoing aspects of the invention provide the advantages of reducing the electric power required to operate a CZ grower, while increasing the speed with which the melt temperature can be raised or lowered in a controlled manner. Also, the lifetime of heater components is extended and production of contaminating gases from the heater elements can be greatly reduced, resulting in higher quality ingots.

### BRIEF DESCRIPTION OF THE DRAWINGS

The drawings are heuristic for clarity. The foregoing and other features, aspects and advantages of the invention will become better understood with regard to the following description, appended claims and accompanying drawings in which:

FIG. 1 is a schematic side view of a CZ system in accordance with an aspect of the present invention.

FIG. 2 is a data plot showing the decrease in temperature of molten silicon as solid silicon is added to the melt in accordance with an aspect of the present invention.

### DETAILED DESCRIPTION

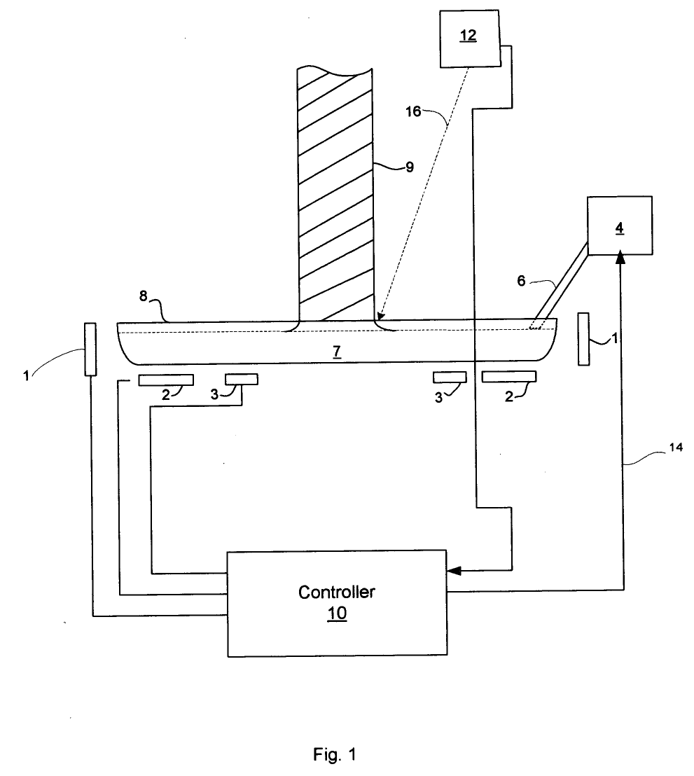

Referring to FIG. 1, a crystal growing system according to an aspect of the present invention provides a crucible 8 containing melt 7 from which an ingot 9 is being pulled. During the crystal pulling process, it is desirable to modify characteristics of the crystal being pulled, such as the rate of crystal solidification or the crystal diameter. One of the preferred means of doing this is by altering the melt temperature.

According to an aspect of the present invention, solid feedstock 5 may be added from feeder 4 through tube 6. This added solid feedstock material is at a much lower temperature than the surrounding melt and absorbs heat from the melt as the solid feedstock material's temperature rises, and as the solid material itself melts. As the solid feedstock material absorbs energy from the melt, the temperature of the melt falls immediately. This has been found to provide a very efficient, highly controllable means for cooling the melt and maintaining a desired melt temperature. The amount of solid material added is controlled by feeder 4 responsive to activation signals from controller 10 so that the amount of cooling is precisely determined. Therefore this aspect of the invention provides prompt, efficient and precise control of melt cooling.

As shown in FIG. 1, according to an aspect of the present invention, heaters 1, 2, and 3 are disposed around crucible 8 to provide heat to the contents of the crucible. Heater 1 is generally cylindrical in shape and provides heat from to the sides of the crucible. Heaters 2 and 3 provide heat to the bottom of the crucible. In a preferred embodiment, heaters 2 and 3 are generally annular in shape. Heaters 1, 2 and 3 are resistive heaters coupled to controller 10, which controllably applies electric current to the heaters 1, 2, 3 to alter their temperature. A sensor 12, such as a pyrometer or like temperature sensor, provides a continuous measurement as shown at 16 of the temperature of the melt at the crystal/melt interface of the growing single crystal ingot 9. Sensor 12 also may be directed to measure the temperature of the growing ingot. Sensor 12 is communicatively coupled with controller 10. Other temperature sensors may be added to measure and provide temperature feedback to the controller with respect to points that are critical to the growing ingot. While a communication lead is shown for clarity, the communication link between one or more temperature sensors and controller may be wireless, such as by an infra red data link, as is well known by those skilled in the art.

According to an aspect of the present invention, the amount of current applied to each of the heaters 1, 2, and 3 by controller 10 may be separately and independently chosen to optimize the thermal characteristics of the melt. Preferred embodiments of the present invention may employ one or a plurality of heaters disposed around the crucible to provide heat.

According to an aspect of the present invention, controller 10 has a control lead coupled with feeder 4 for providing activation signals to the feeder to introduce a desired amount of solid feedstock into the melt through tube 6. The controller is provided with a look up table containing values for optimal amounts of feedstock introduction to achieve and/or maintain desired temperature levels in the melt and at the melt/crystal interface. In response to feedback signals from sensor 12, controller 10 controllably activates feeder 4 to release feedstock into the melt to control accurately melt temperature for optimal ingot growth.

The capability to control melt temperature and cool the melt rapidly by adding solid feedstock from feeder 4 reduces the need to provide other means to conduct heat out of crucible 8 for the purpose of cooling the melt. The controlled addition of solid feedstock to the crucible has been found effective as the dominant control mechanism for controlling melt temperature in the crucible quickly, accurately and with high thermal efficiency. Therefore, an aspect of the invention makes possible the use of a crucible and heater combination that very efficiently transfers heat to the crucible, while reducing the heater power required and reducing operating temperature of the heater elements 1, 2, and 3. Reducing the temperature of the heater elements prolongs their useful lifetime. Reducing the operating temperature of the heater elements also can reduce the production of gases from the melt that have a deleterious effect on the growing ingot.

In a conventional CZ process, the heater elements are made of graphite and the crucible is made of silicon dioxide (quartz). When employed to grow single crystal silicon ingots, a quartz crucible typically generates oxide gases that can react with the graphite heaters to produce carbon monoxide gas. The rate of carbon monoxide production increases rapidly with increasing heater temperature. This gas can contact the silicon melt and be absorbed, increasing the carbon content of the melt. Carbon in the melt can be absorbed into the crystal being grown, changing the crystal's physical properties and making it less valuable, or even useless, for some commercial applications. Therefore, the ability to operate the crucible heaters at lower temperatures, effectively according to an aspect of the invention greatly reduces carbon monoxide production and carbon contamination of ingots as compared to a conventional CZ process.

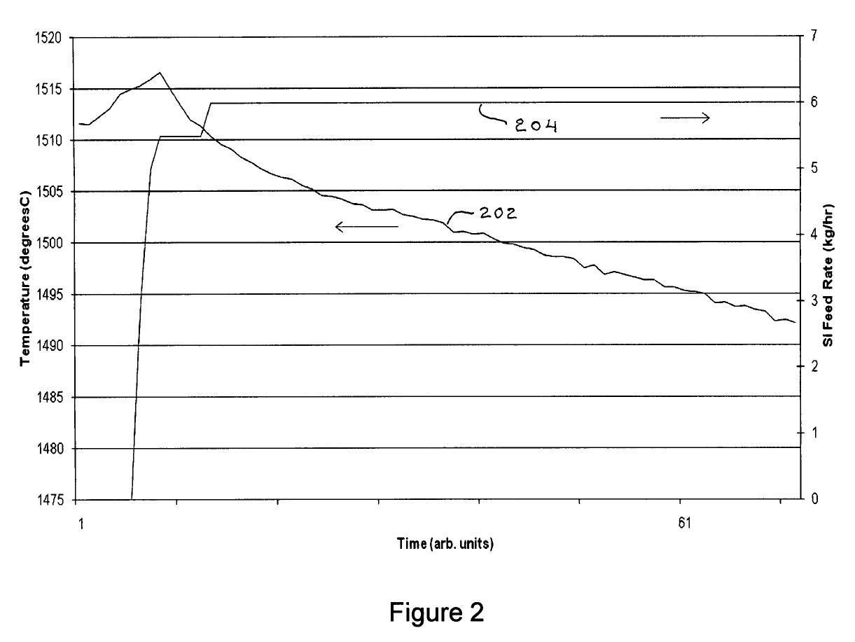

FIG. 2 is an operational example providing a data plot showing the decrease in temperature of molten silicon as solid silicon is added to the melt. A data plot 202 of a locus of points shows silicon melt temperature as a function of time with a constant feed rate. 204 shows a feed rate of 6 kg of silicon per hour. Thus, referring to FIG. 2, an optimal temperature for molten silicon and crystal growth can be achieved rapidly and with great thermal efficiency by a controlling feed rate of solid feed stock.

While the invention has been described in connection with what are presently considered to be the most practical and preferred embodiments, it is to be understood that the invention is not limited to the disclosed embodiments and alternatives as set forth above, but on the contrary is intended to cover various modifications and equivalent arrangements included within the scope of the forthcoming claims. For example, other materials that are amenable to being grown by the CZ process may be employed as the melt material, such as gallium arsenide, gallium phosphide, sapphire, and various metals, oxides and nitrides.

Also, other materials that are resistant to breakdown by molten silicon, such as ceramic coatings, or various metals, oxides, nitrides, and combinations thereof can be used for the composition of the crucible. In addition, other materials may be used for heaters, such as molybdenum or tungsten. Therefore, persons of ordinary skill in this field are to understand that all such equivalent arrangements and modifications are to be included within the scope of the following claims.

We claim:

1. A CZ system for growing a single crystal ingot from a molten material comprising:
a crucible including a base and side walls for holding a quantity of molten material at a melt/crystal interface with respect to a seed crystal for growing an ingot from the molten material;
a feeder for providing solid feedstock material to the crucible where it is melted;
heaters disposed beneath the base and around the sidewalls for providing heat to the crucible;
one or more sensors directed at the melt/crystal interface to provide an output signal representative of sensed temperature at the melt/crystal interface;
an insulated thermal environment surrounding the heater means to minimize energy loss through the process chamber walls; and
a controller responsive to the sensor output signal and having a control lead for activating the feeder, the controller including a lookup table containing values for optimal amounts of feedstock, the controller being programmed such that adding solid feedstock provides dominant control of the temperature of the molten material in the crucible.

2. CZ system as in claim 1, wherein the introduction of solid feedstock provides direct, immediate control of the latent heat of fusion with respect to the melt/crystal interface.

3. A continuous CZ system for growing single crystal ingots from a molten material comprising:
a crucible including a base and side walls for holding a quantity of molten material at a melt/crystal interface with respect to a seed crystal for growing an ingot from the molten material;
a feeder for adding solid feedstock material to the crucible upon receipt of an activation signal;
heaters disposed beneath the base and around the sidewalls for providing heat to the crucible;
insulators surrounding the heater means to minimize energy loss to the process chamber; and
a controller responsive to temperature of the molten material and/or melt crystal interface, having a control output lead for activating the feeder, the controller programmed to add solid feedstock to the molten material to control the temperature of the melt/crystal interface by the latent heat of fusion to provide dominant control of the temperature of the melt/crystal interface in the crucible.

4. (canceled)

5. A CZ system as in claim 1, wherein at least one of the one or more sensors includes a direct line of sight to one of the melt surface and the melt/crystal interface.

6. A CZ system as in claim 1, wherein the controller is programmed to add solid feedstock to the molten material to alter the rate of crystal solidification and/or the crystal diameter.

7. A CZ system as in claim 1, wherein the heaters are resistive heaters.

8. A CZ system as in claim 7, wherein the heaters are annular and fabricated from graphite.

9. A CZ system as in claim 7, wherein the controller is programmed to control the amount of current to each heater to adjust the adjust characteristics of the melt.

10. A CZ system as in claim 1, wherein the crucible is fabricated from quartz.

11. A CZ system as in claim 1, wherein one or more of the sensors are directed at the crystal to provide an output signal representative of sensed temperature at the crystal.

12. A CZ system as in claim 3, further comprising one or more sensors directed at the melt/crystal interface to provide an output signal representative of sensed temperature at the melt/crystal interface.

13. A CZ system as in claim 3, further comprising one or more sensors directed at the crystal to provide an output signal representative of sensed temperature at the crystal.

14. A CZ system as in claim 12, wherein at least one of the one or more sensors includes a direct line of sight to one of the melt surface and the melt/crystal interface.

15. A CZ system as in claim 3, wherein the controller is programmed to add solid feedstock to the molten material to alter the rate of crystal solidification and/or the crystal diameter.

16. A CZ system as in claim 3, wherein the heaters are resistive heaters.

17. A CZ system as in claim 16, wherein the heaters are annular and fabricated from graphite.

18. A CZ system as in claim 16, wherein the controller is programmed to control the amount of current to the each heater to adjust the thermal characteristics of the melt.

19. A CZ system as in claim 3, wherein the crucible is fabricated from quartz.
